(19) United States
(12) Patent Application Publication
(10) Pub. No.: US 2010/0309358 A1
(43) Pub. Date: Dec. 9, 2010

(54) SOLID-STATE IMAGING DEVICE

(75) Inventor: Junichi Yamamoto, Kanagawa (JP)

Correspondence Address: YOUNG & THOMPSON, 209 Madison Street, Suite 500, Alexandria, VA, 22314, US

(73) Assignee: RENESAS ELECTRONICS CORPORATION, Kanagawa (JP)

(21) Appl. No.: 12/791,087

(22) Filed: Jun. 1, 2010

(30) Foreign Application Priority Data
Jun. 5, 2009 (JP) 2009-8668
Jun. 5, 2009 (JP) 2009-136134

(51) Int. Cl. H04N 5/335; H01L 31/18

(52) U.S. Cl. 348/311; 438/60; 348/E05.091; 257/E31.053

(57) ABSTRACT

A solid-state imaging device includes: a photoelectric conversion section (PCS) generating signal charge from light; a charge accumulating section (CAS) accumulating the signal charge; a first charge transfer section (CTS1) between the PCS and the CAS transferring the signal charge from the PCS to the CAS responsive to a control signal; and a second charge transfer section (CTS2) provided for the CAS to transfer the signal charge from the CAS in response to a control signal. The CAS includes: a charge accumulation gate electrode; and a gate insulating film between the charge accumulation gate electrode and a semiconductor substrate. The gate insulating film includes: a first region (R1) provided on a side of CTS1 in a region corresponding to the CAS; and a second region (R2) provided on a side of CTS2 in the region corresponding to the CAS. R2's gate insulating film is thicker than R1's.

### INCORPORATION BY REFERENCE

This patent application claims a priority on convention based on Japanese Patent application No. 2009-136134 filed on Jun. 5, 2009. The disclosure thereof is incorporated herein by reference.

### TECHNICAL FIELD

The present invention relates to a solid-state imaging device.

### BACKGROUND ART

A solid-state imaging device is mounted on a linear sensor used for an image pick-up device such as an auto-focusing sensor and scanner. The solid-state imaging device is also called a CCD imaging sensor, and includes a photodiode for carrying out photoelectric conversion to received light and an accumulating section for carrying out accumulation of charges obtained through the photoelectric conversion. In the CCD imaging sensor, as the accumulation time becomes long, a dark current sometimes increases to considerably degrade an image. A solid-state imaging device which can reduce the dark current is known (patent literatures 1 to 3).

The patent literature 1 discloses the solid-state imaging device which can reduce the dark current. FIG. 1 is a plan view showing a configuration of the solid-state imaging device disclosed in the patent literature 1. The solid-state imaging device 101 includes a photoelectric conversion section 102, an auxiliary charge accumulating section 103, a first control section 104, a charge accumulating section 105, a second control section 106, and a charge transfer section 108. FIG. 2 is a cross sectional view of the solid-state imaging device 101 along the X-X′ line in FIG. 1.

In the solid-state imaging device 101, a signal charge generated by incidence of light to the photoelectric conversion section 102 is accumulated in a potential well of the auxiliary charge accumulating section 103. The accumulated signal charge moves into a potential well of the charge accumulating section 105 by opening a first control gate 104 in response to a clock signal φTG1 of a “high” level. Then, the first control gate 104 is closed in response to the clock signal φTG1 of a “low” level. Subsequently, the accumulated signal charge is transferred under a gate electrode 182 of the charge transfer section 108 by opening a second control gate 106 in response to a clock signal φTG2 of the “high” level.

As described above, since the potential of the second control section 106 on the side of the charge transfer section 108 is higher than that of the first control section 104, and an electrode 143 of the first control section 104 is formed over a first region 111 and a second region 112, the signal charge can be smoothly transferred from the photoelectric conversion section 102 to the auxiliary accumulating section 103, the first control section 104, the charge accumulating section 105, the second control section 106, and the charge transfer section 108. Additionally, in the operation, a surface of a semiconductor substrate will be in a pinning state showing a P-type, which can suppress the generation of the dark current. This can be described as follows.

A constant negative-voltage is applied to a first accumulate gate electrode 132 of the auxiliary accumulating section 103. For this reason, an interface between the first region 111 and a first accumulation gate insulating film 131 is reversed into the P-type, that is, is set to the pinning state, and the surface potential becomes a GND potential. Accordingly, thermal electrons that are generated due to crystal defects present in interface of the gate insulating film 131 are recombined with holes present in the P-type semiconductor in the inverted state, to be hard to influence the accumulated signal charge.

For this reason, degradation of the signal charge due to the dark current can be suppressed, and the accumulation of signal charge for a long time or under a high temperature can be made possible. The photoelectron conversion section 102 has a so-called PIN photodiode structure of a first region 111 of an N-type and a P′-type region 121 whose concentration is higher than that of the semiconductor (silicon) substrate 110, and can have a characteristic substantially equal to that of the first region 111. Meanwhile, since a constant negative voltage is also applied to the accumulation gate electrode 152 of the charge accumulating section 105, the pinning state will appear in which an interface with a second accumulation gate insulating film 151 in the second region 112 will be inverted into the P-type.

FIG. 3 is a plan view showing a configuration of a solid-state imaging device disclosed in the patent literature 3. FIG. 4 is a cross sectional view of the solid-state imaging device along the line Y-Y′ in FIG. 3. According to the patent literature 3, in a Frame Interline Transfer (FIT) type solid-state imaging element, an electric field intensity in the accumulating section 202 is suppressed by reducing the thickness W1 of a gate insulating film of a light receiving section 201 and increasing the thickness W2 of a gate insulating film of the accumulating section 202, and thus the dark current is prevented from generating in the accumulating section 202.

### CITATION LIST

Patent literature 1: JP 2008-258571A
Patent literature 2: JP-B-Heisei 8-10760
Patent literature 3: JP-A-Heisei 4-137763

### SUMMARY OF THE INVENTION

The solid-state imaging device having an electric accumulating section is applied to various application fields. However, in an auto-focusing image sensor, it is specially required that an accumulation time can be changed in a wide range because of necessity to focus the sensor under a condition that there is an extraordinarily wide difference of light intensity from imaging of a night view to imaging under sunlight. Moreover, as the periphery becomes dark, a signal charge amount from a subject is less. Accordingly, it is required to reduce a dark current generated in the photoelectric conversion section and the charge accumulating section, that is, noise generated from the sensor itself.

However, since the signal charge obtained in the photoelectric conversion section is amplified in an output circuit, a leakage current generated in the charge accumulating section causes a problem as a noise, even if it is in an order of 1 to 10 fA. In a structure of the solid-state imaging device 101 disclosed in the patent literature 1, since the voltage of approximately −10V is applied to the accumulation gate electrode, the leakage current is generated as the noise due to electric field between the accumulation gate and the semiconductor substrate surface and between the accumulation gate and the control gate adjacent to the accumulation gate. When the voltage is changed from −10V toward 0V to ease the electric field, the pinning state in the interface of the gate insulating film cannot be maintained and accordingly a dark current characteristic is degraded.

Additionally, in the case of the patent literature 3, a gate insulating film of a V register in the accumulating section 202 is made thick so that the charge transfer to an H register 203 becomes slow.

In an aspect of the present invention, a solid-state imaging device includes: a photoelectric conversion section configured to generate signal charge from light inputted thereto; a charge accumulating section configured to accumulate the signal charge supplied; a first charge transfer section provided between the photoelectric conversion section and the charge accumulating section to transfer the signal charge from the photoelectric conversion section to the charge accumulating section in response to a control signal; and a second charge transfer section provided for the charge accumulating section to transfer the signal charge from the charge accumulating section in response to a control signal. The charge accumulating section includes: a charge accumulation gate electrode; and a gate insulating film provided between the charge accumulation gate electrode and a semiconductor substrate. The gate insulating film includes: a first region provided on a side of the first charge transfer section in a region corresponding to the charge accumulating section; and a second region provided on a side of the second charge transfer section in the region corresponding to the charge accumulating section. A thickness of the gate insulating film in the second region is thicker than that of the gate insulating film in the first region.

In another aspect of the present invention, a method of manufacturing a solid-state imaging device, is achieved by forming a first insulating film on a semiconductor substrate in a region for a charge accumulating section; by selectively removing the first insulating film to expose the semiconductor substrate in a first region of the region for the charge accumulating section; by forming a second insulating film to cover the exposed semiconductor substrate and the remaining first insulating film; and by forming a charge accumulation gate electrode on the second insulating film.

According to the present application, an accumulation time of a signal charge obtained through the photoelectric conversion can be controlled to enlarge a dynamic range in the solid-state imaging device.

### BRIEF DESCRIPTION OF THE DRAWINGS

The above and other objects, advantages and features of the present invention will be more apparent from the following description of certain embodiments taken in conjunction with the accompanying drawings, in which:

FIG. 1 is a plan view showing a configuration of a solid-state imaging device disclosed in patent literature 1;

FIG. 2 is a cross sectional view showing the solid-state imaging device shown in FIG. 1;

FIG. 3 is a diagram showing a configuration of a conventional solid-state imaging device;

FIG. 4 is a cross sectional view showing the configuration of the conventional solid-state imaging device shown in FIG. 3;

FIG. 5 is a diagram showing a configuration of a solid-state imaging device according to an embodiment of the present invention; and

FIGS. 6A to 6D are cross-section views showing a manufacturing process of the solid-state imaging device according to the embodiment.

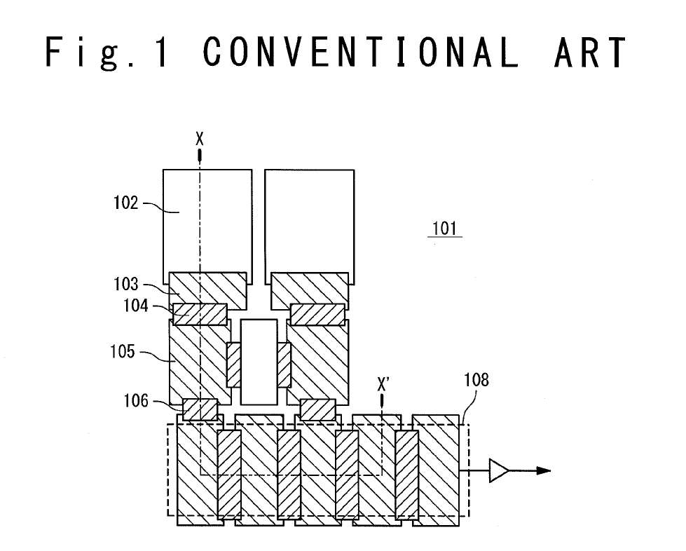

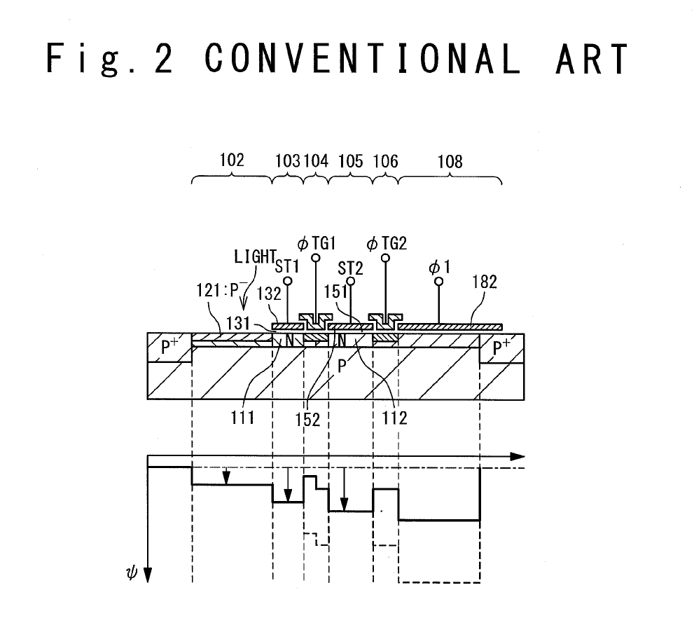

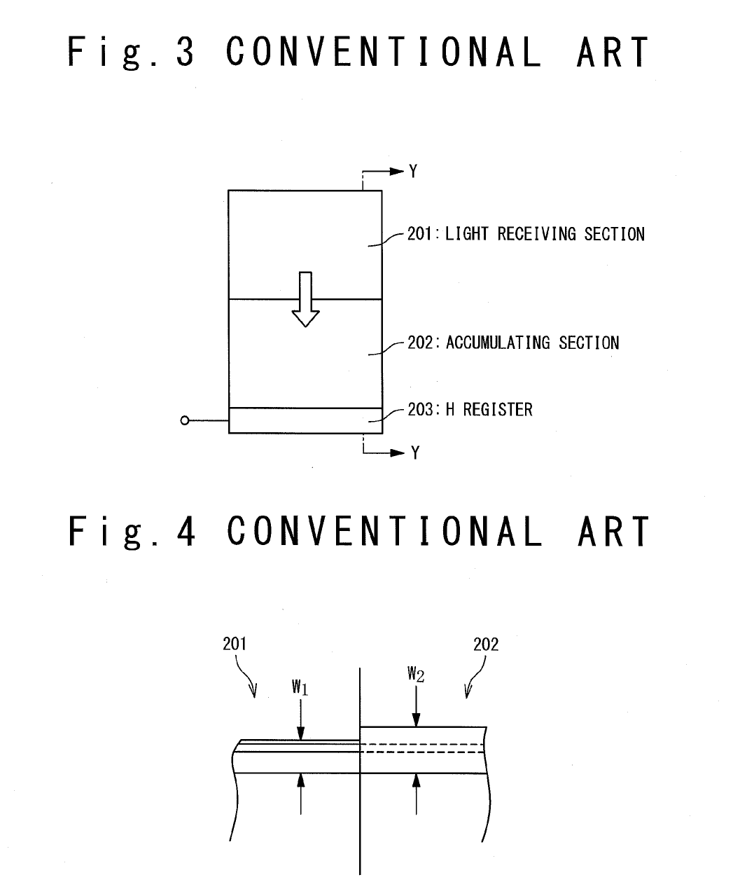

### DESCRIPTION OF EMBODIMENTS

Hereinafter, a solid-state imaging device of the present invention will be described in detail with reference to the attached drawings. It should be noted that the same numerals are assigned to the same components, and the repetitive description thereof will be omitted.

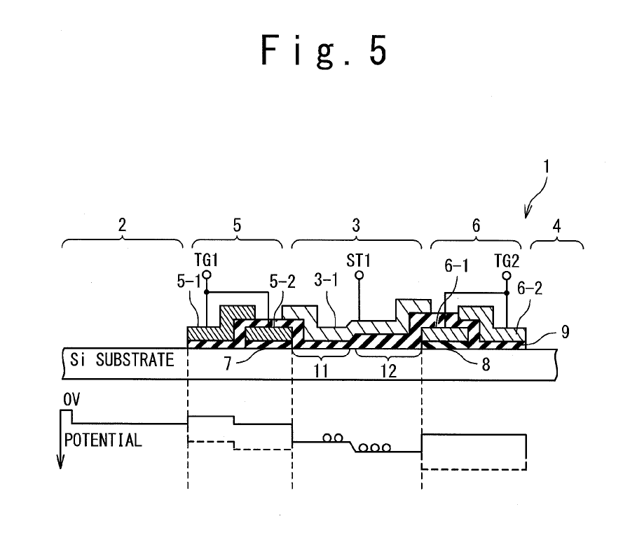

An upper portion of FIG. 5 is a cross sectional view showing a configuration of a solid-state imaging device 1 according to the present embodiment. A lower portion of FIG. 5 is a potential chart showing an operation of the solid-state imaging device 1.

Referring to FIG. 5, the solid-state imaging device 1 of the present embodiment includes a light-receiving section 2, a charge accumulating section 3, a CCD section 4, a first charge transfer section 5, and a second charge transfer section 6.

The first charge transfer section 5 includes a first gate electrode 5-1 formed a silicon substrate through a second gate insulating film 9 and a second gate electrode 5-2 formed on the silicon substrate through a first gate insulating film 7. A part of the first gate electrode 5-1 extends above the second gate electrode 5-2. Impurity is implanted into a region of the silicon substrate which is located below the second gate electrode 5-2 and its periphery. The second charge transfer section 6 includes a first gate electrode 6-1 formed on the silicon substrate through the first gate insulating film 8 and a second gate electrode 6-2 formed on the silicon substrate through the second gate insulating film 9. A part of the second gate electrode 6-2 extends above the first gate electrode 6-1 through the second gate insulating film 9. The charge accumulating section 3 includes a gate electrode 3-1 formed on the silicon substrate through the second gate insulating film 9. A part of the gate electrode 3-1 extends above the second gate electrode 5-2 through the second gate insulating film 9 and another port of the gate electrode 3-1 extends above the first gate electrode 6-1 through the second gate insulating film 9. The charge accumulating section 3 is composed of a first region 11 and a second region 12. In the charge accumulating section 3, the second gate insulating film 9 is formed to be thicker in the second region 12 than that in the first region 11. In other words, the film thickness of the second gate insulating film 9 in the second region 12 is formed to be thicker than that of the second gate insulating film 9 in the first region 11. A control voltage TG1 is applied to the first and second gate electrode 5-1 and 5-2 of the first charge transfer section 5. Also, a control voltage TG2 is applied to the first and second gate electrode 6-1 and 6-2 of the second charge transfer section 5. A control voltage ST1 is applied to the gate electrode 3-1. In this way, the potential well in the first transfer section 5 has a step. Also, in the charge accumulating section 3, the potential well has a step.

By the above-mentioned structure, in the solid-state imaging device having a 2-layer gate electrode configuration according to the present embodiment, the potential wells are formed as shown in FIG. 5. In the first and second charge transfer sections 5 and 6, the depths of the potential wells are changed a level shown by a solid line and a level shown by a broken line depending on the control voltage TG1 and TG2, respectively.

Signal charges are generated based on light incident to the light-receiving section 2. At this time, the first charge transfer section 5 is set to a state of a deep potential well based on the control voltage TG1, so that the signal charges move to the first charge transfer section 5. Then, the first charge transfer section 5 is changed to a state of a shallow potential well based on the control voltage TG1, so that the signal charges move to the charge accumulating section 3. At this time, since the first charge transfer section 5 has a step portion in the potential well, the signal charges rapidly move to the charge accumulating section 3. Also, the second charge transfer section 6 is set to a state of a shallow potential well based on the control voltage TG2. Therefore, the signal charges are accumulated in the charge accumulating section 3. In this case, since the step is formed in the potential well of the charge accumulating section 3 due to the difference in the thickness of the gate insulating film 9, the signal charges are easy to be collected in the second region 12 of the charge accumulating section 3. After that, the second charge transfer section 6 is set to a state of a deep potential well, so that the signal charges move from the charge accumulating section 3 to the CCD section 4 through the second charge transfer section 6.

In this way, the thickness of the gate insulating film 9 in the charge accumulating section 3 is increased from the first region 11 to the second region 12 in the charge transfer direction, to generate an electric field in that direction. Thus, the signal charges are smoothly transferred without generating noise.

A leakage current functioning as noise is reduced by increasing the thickness of the gate including film 9 of the charge accumulating section 3 in the second region 12 to ease the electric field between the accumulation gate electrode 3-1, the semiconductor substrate surface, and the adjacent transfer gates 5-2 and 6-1. In addition, since the thickness of the gate insulating film 9 of the charge accumulating section 3 is increased in the charge transfer direction, the electric field is generated in a region of the gate electrode 3-1 so as to prevent decrease of the charge transfer speed. Control sections and the charge transfer sections have the same thickness of the gate insulating films as that of the conventional example, and accordingly other performances can be maintained.

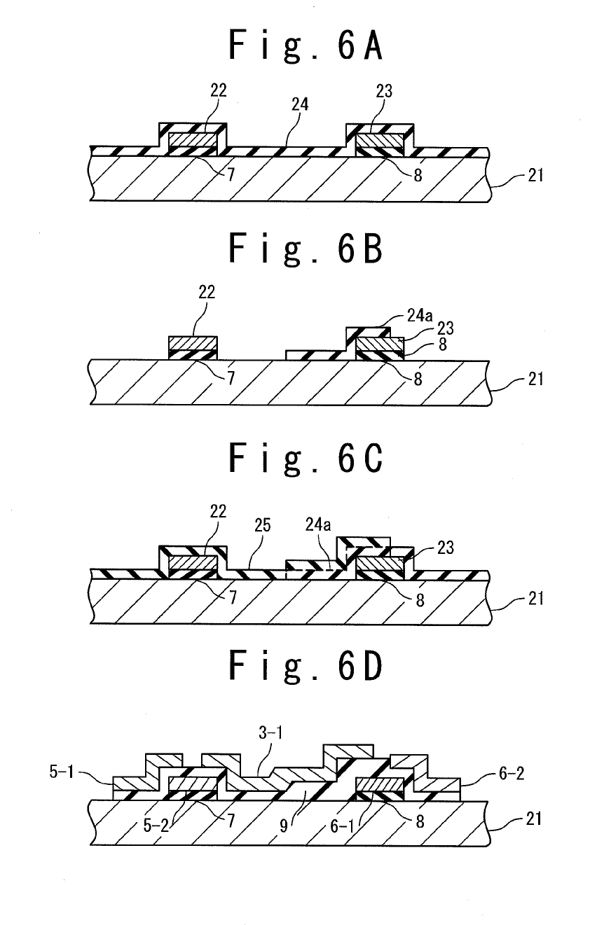

A manufacturing process of the solid-state imaging device 1 according to the present embodiment will be described below. FIG. 6A is a cross sectional view showing a first stage of the manufacturing process of the solid-state imaging device 1 according to the present embodiment. In the first stage, impurity implantation is performed in a region of the semiconductor substrate corresponding to the gate electrode 5-2. Then, the first gate insulating film is formed on the semiconductor substrate to have the thickness of 800 Å and a polysilicon film is formed and patterned on the first gate insulating film. Thus, lower layer gates 22 and 23 are formed as the gate electrodes 5-2 and 6-1. Then, the first gate insulating film is removed by using the lower layer gates 22 and 23 as a mask. Thus, the first gate insulating film 7 and the first gate insulating film 8 are formed on the semiconductor substrate 21. Subsequently, a second oxide film 24 is formed to have the thickness of 200 Å on the whole semiconductor substrate.

FIG. 6B is a cross section view showing a second stage of the manufacturing process of the solid-state imaging device 1. In the second stage, a portion of the second oxide film 24 other than the second region 12 of the charge accumulating section 3 is removed or etched in a lithography process. In this manner, a remaining oxide film 24a is formed in the second region 12 of the charge accumulating section 3.

FIG. 6C is a cross section view showing a third stage of the manufacturing process of the solid-state imaging device 1. In the third stage, a third oxide film 25 is formed on the whole semiconductor substrate 21 to have the thickness of 1000 Å. The third oxide film 25 is also formed on the remaining oxide film 24a that has been formed on the second region 12 of the charge accumulating section 3. In this process, the thickness of the oxide film on the second region 12 of the charge accumulating section 3 will become 1100 Å.

FIG. 6D is a cross section view showing a fourth stage of the manufacturing process of the solid-state imaging device 1. In the fourth stage, the first gate electrode 5-1 in the first charge transfer section 5, the gate electrode 3-1 in the charge accumulating section 3, and the second gate electrode 6-2 in the second charge transfer section 6 are formed. The oxide film 25 and the remaining oxide film 24a function as the second gate insulating film 9. The second gate insulating film 9 has the thickness of 1100 Å only in the second region 12 of the charge accumulating section 3, and has a thickness of 1000 Å in other regions.

As described above, the solid-state imaging device 1 according to the present embodiment has the charge accumulating section 3 in a change transfer route from the photoelectric conversion section (a pixel section) 2 to the charge transfer section (a CCD section) 4. In the solid-state imaging device 1, the configuration where the thickness of the gate insulating film 9 in the second region 12 of the charge accumulating section 3 is increased to be thicker than the thickness of other region of the gate insulating film 9 toward the charge transfer direction 4. In this manner, the accumulation time can be widely varied, and even when an output circuit having a high amplification factor is mounted, the solid-state imaging device without dark current can be provided.

The embodiments of the present invention have been specifically described above. However, the present invention is not limited to the above-mentioned embodiments and can be variously modified within the scope of the present invention. For example, when a design rule for a gate electrode interval is reduced, a configuration of a single-layer gate electrode can be adopted. Even in such a case, by only increasing the thickness of the gate insulating film in a partial region of the accumulation gate, the same effect can be obtained.

What is claimed is:

1. A solid-state imaging device comprising:
a photoelectric conversion section configured to generate signal charge from light inputted thereto;
a charge accumulating section configured to accumulate the signal charge supplied;
a first charge transfer section provided between said photoelectric conversion section and said charge accumulating section to transfer the signal charge from said photoelectric conversion section to said charge accumulating section in response to a control signal;
a second charge transfer section provided for said charge accumulating section to transfer the signal charge from said charge accumulating section in response to a control signal,
wherein said charge accumulating section comprises:
a charge accumulation gate electrode; and
a gate insulating film provided between said charge accumulation gate electrode and a semiconductor substrate,
wherein said gate insulating film comprises:
a first region provided on a side of said first charge transfer section in a region corresponding to said charge accumulating section; and
a second region provided on a side of said second charge transfer section in the region corresponding to said charge accumulating section,
wherein a thickness of said gate insulating film in said second region is thicker than that of said gate insulating film in said first region.

2. The solid-state imaging device according to claim 1, wherein said charge accumulation gate electrode comprises:
a first section provided above said first region; and
a second section provided on said second region,
wherein said first section and said second section are formed as a unitary body.

3. The solid-state imaging device according to claim 2, wherein said gate insulating film in said first and second regions is formed to generate electric field from said first region to said second region due to difference in film thickness between said first region and said second region.

4. The solid-state imaging device according to claim 3, wherein the film thickness of said gate insulating film in said first region is substantially 1000 Å, and the film thickness of said gate insulating film in said second region is substantially 1100 Å.

5. A method of manufacturing a solid-state imaging device, comprising:
forming a first insulating film on a semiconductor substrate in a region for a charge accumulating section;
selectively removing said first insulating film to expose said semiconductor substrate in a first region of the region for said charge accumulating section;
forming a second insulating film to cover the exposed semiconductor substrate and the remaining first insulating film; and
forming a charge accumulation gate electrode on said second insulating film.

6. The method according to claim 5, wherein said forming a first insulating film comprises:
forming a first layer gate insulating film on said semiconductor substrate;
forming first and second gate electrodes for first and second charge transfer sections on said first layer gate insulating film, wherein said first charge transfer section is provided between a photoelectric conversion section and said charge accumulating section and said second charge transfer section is connected to said charge transfer section; and
forming said first insulating film to cover said first layer gate electrode and said semiconductor substrate.

7. The method according to claim 6, wherein said selectively removing comprises:
forming a resist mask to cover said first insulating film in said first region; and
removing said first insulating film other than said first region.

8. The method according to claim 7, wherein said forming a second insulating film comprises:
forming said second insulating film on said first insulating film in said first region.
